(19) United States
(12) Patent Application Publication
(10) Pub. No.: US 2026/0309758 A1
(43) Pub. Date: Oct. 8, 2026

(54) UTILITY METER WITH ENHANCED COMMUNICATION, DATA STORAGE, AND FIRMWARE UPDATE CAPABILITIES

(71) Applicant: EI ELECTRONICS LLC, D/B/A ELECTRO INDUSTRIES/GAUGE TECH, Westbury, NY (US)

(72) Inventors: Tibor Banhegyesi, Northport, NY (US); Jorge Arturo Polar Seminario, Winter Park, FL (US)

(21) Appl. No.: 19/637,423

(22) Filed: Apr. 2, 2026

Related U.S. Application Data
(60) Provisional application No. 63/782,855, filed on Apr. 3, 2025.

(51) Int. Cl. G01R 21/133; G06F 8/65

(52) U.S. Cl. CPC G01R 21/1333; G06F 8/65

(57) ABSTRACT

A utility meter system can include a plurality of meters connected to a head-end system configured to provide firmware updates to the utility meters. The utility meters can receive updates from the head end system and communicate meter data to the headend system. The utility meter system can include a processing system configured to implement multiple communication protocols. The processing system can further implement a self-describing database in memory, the database storing objects associated with the meter and metadata about the objects. The utility meter system can support configuration and firmware updates using structured data files, including JSON files that are parsed, validated, and applied to update meter configuration. The system can also support firmware update files created in a hex format that are converted, sectioned, compressed, encrypted, assembled with a file header, and verified prior to application.

### RELATED APPLICATIONS

This application is based on U.S. provisional application Serial No. 63/782,855, filed Apr. 3, 2025, the disclosure of which is incorporated herein by reference in its entirety and to which priority is claimed.

### FIELD

The present disclosure is directed to intelligent electronic devices for utility systems, such as smart meters that can record and communicate utility usage information.

### BACKGROUND

Monitoring electrical energy by consumers and providers of electric power is a fundamental function within any electric power distribution system. Electrical energy may be monitored for purposes of usage, equipment performance and power quality. Electrical parameters that may be monitored include volts, amps, watts, vars, power factor, harmonics, kilowatt hours, kilovar hours and any other power related measurement parameters. Typically, measurement of the voltage and current at a location within the electric power distribution system may be used to determine the electrical parameters for electrical energy flowing through that location.

Devices that perform monitoring of electrical energy may be electromechanical devices, such as, for example, a residential billing meter or may be an intelligent electronic device (“IED”). Intelligent electronic devices typically include some form of a processor. In general, the processor is capable of using the measured voltage and current to derive the measurement parameters. The processor operates based on a software configuration. A typical consumer or supplier of electrical energy may have many intelligent electronic devices installed and operating throughout their operations. IEDs may be positioned along the supplier's distribution path or within a customer's internal distribution system. IEDs include revenue electric watt-hour meters, protection relays, programmable logic controllers, remote terminal units, fault recorders and other devices used to monitor and/or control electrical power distribution and consumption. IEDs are widely available that make use of memory and microprocessors to provide increased versatility and additional functionality. Such functionality includes the ability to communicate with remote computing systems, either via a direct connection, e.g., a modem, a wireless connection or a network. IEDs also include legacy mechanical or electromechanical devices that have been retrofitted with appropriate hardware and/or software allowing integration with the power management system.

Typically, an IED is associated with a particular load or set of loads that are drawing electrical power from the power distribution system. The IED may also be capable of receiving data from or controlling its associated load. Depending on the type of IED and the type of load it may be associated with, the IED implements a power management function that is able to respond to a power management command and/or generate power management data. Power management functions include measuring power consumption, controlling power distribution such as a relay function, monitoring power quality, measuring power parameters such as phasor components, voltage or current, controlling power generation facilities, computing revenue, controlling electrical power flow and load shedding, or combinations thereof.

Conventional IEDs include the ability to communicate with remote computing systems. Traditionally, IEDs would transfer data using serial based download commands. These commands would be accessed via an RS232, and RS485 or an Ethernet port encapsulating the serial request with an Ethernet message using any Ethernet protocol such as HTTP or TCP/IP. For instance, host software or a “master” would make a request for a set of data from one or more memory registers in an IED slave. At that point, the IED slave would then communicate the data stored in the memory registers back to the host software utilizing a serial transfer. A need exists for systems and methods for efficiently collecting data from various devices, e.g., IEDs. A further need exists for systems and methods for analyzing and reporting such collected data.

### SUMMARY

In certain configurations, a utility meter includes a housing with at least one sensor connected to the housing and configured to be connected to a utility system. The at least one sensor configured for measuring at least one parameter of the utility system and generating at least one analog signal indicative of the at least one parameter. At least one analog to digital converter connected to the at least one sensor. The at least one analog to digital converter configured to receive the at least one analog signal and convert the at least one analog signal to an at least one digital signal to obtain measured data. A processing system includes one or more processors. The processing system is configured to receive the at least one digital signal. A communication interface is connected to the processing system. The processing system includes at least one processor configured to have a first virtual environment and a second virtual environment. The first virtual environment includes a first communication stack and a first library configured to enable communication via a first protocol. The second virtual environment includes a second communication stack and a second library configured to enable communication via a second protocol different than the first protocol.

In certain implementations, a method of providing utility meter communication over multiple protocols includes configuring a processor of a utility meter having a processing system and a communication interface to have a first virtual environment and a second virtual environment. The first virtual environment is configured to include a first communication stack and a first library configured to enable communication via a first protocol. The second virtual environment is configured to include a second communication stack and a second library configured to enable communication via a second protocol different than the first protocol.

In certain configurations, a utility meter includes a housing and at least one sensor connected to the housing and configured to be connected to a utility system. The at least one sensor is configured for measuring at least one parameter of the utility system and generating at least one analog signal indicative of the at least one parameter. At least one analog to digital converter is connected to the at least one sensor. The at least one analog to digital converter is configured to receive the at least one analog signal and convert the at least one analog signal to an at least one digital signal to obtain measured data. A processing system includes one or more processors. The processing system configured for receiving the at least one digital signal. Memory is connected to the processing system. The memory includes at least one memory location. The processing system includes at least one processor configured to implement a self-describing database, the self-describing database including an object associated with the meter and metadata associated with the object.

In certain implementations, a method of updating a utility meter includes creating a JavaScript Object Notation (JSON) file containing one or more configuration parameters for one or more utility meters. The JSON file is uploaded to a utility meter. The utility meter parses the JSON file to extract the configuration parameters. The extracted configuration parameters are validated to determine valid parameters. The valid parameters are applied to update the utility meter configuration. The updated configuration is stored in memory.

In certain implementations, a method of updating a utility meter includes creating an update file in a hex format containing one or more configuration parameters for one or more utility meters. The update file is converted from the hex format to a binary format. The update file is divided into a plurality of sections. Compression and encryption are applied to the sections. A file header is created. The file header is assembled with the sections into a combined file. A checksum value is computed for the combined file. The checksum value is updated in the combined file header. The combined file is transmitted to a utility meter.

In certain configurations, a utility meter system includes a meter housing and at least one sensor connected to the meter housing and configured to be connected to a utility system, the at least one sensor configured for measuring at least one parameter of the utility system and generating at least one analog signal indicative of the at least one parameter. At least one analog to digital converter is connected to the at least one sensor, the at least one analog to digital converter configured to receive the at least one analog signal and convert the at least one analog signal to an at least one digital signal to obtain measured data. A processing system includes one or more processors. A memory has a first region and a second region separate from the first region, wherein the first region includes compiled code having a first library that is used for communicating under a first protocol and the second region includes a second library that is used for communicating under a second protocol, and wherein access to the compiled code is limited by a virtual wrapper, which is configured to conceal implementation details of communication under the second protocol, the memory storing instructions that, when executed by the one or more processors, cause the system to receive instructions to communicate using the first protocol, and execute at least one first service provided by the first library, wherein the at least one first service is accessible via at least one function pointer implementing at least one virtual hook that is disposed in a vector call table in connection with the virtual wrapper.

In certain configurations, one or more non-transitory computer-readable storage media include one or more executable instructions, wherein the one or more instructions, when executed by one or more processors, cause the one or more processors to receive instructions to communicate using a communication protocol, determine that the communication protocol is implemented via one or more functionalities provided by a protocol library, wherein the protocol library is included in an executable program that limits access to the one or more functionalities in the protocol library via a wrapper, access the one or more functionalities in the protocol library via the wrapper by invoking one or more preconfigured functions that correspond to specific functionalities provided by the protocol library, wherein the preconfigured functions are referenced in a vector call table, and execute the one or more functionalities in the protocol library to communicate using the communication protocol.

In certain implementations, a method of managing communications in a meter system includes receiving instructions to communicate using a communication protocol, determining that the communication protocol is implemented via one or more functionalities provided by a library, wherein the library is included in an executable program that limits access to the one or more functionalities in the library via a wrapper, accessing the one or more functionalities in the library via the wrapper by invoking one or more preconfigured functions that correspond to specific functionalities provided by the library, and executing the one or more functionalities in the library to communicate using the communication protocol.

In certain configurations, a utility meter system includes a meter housing and at least one sensor connected to the meter housing and configured to be connected to a utility system, the at least one sensor configured for measuring at least one parameter of the utility system and generating at least one analog signal indicative of the at least one parameter. At least one analog to digital converter is connected to the at least one sensor, the at least one analog to digital converter configured to receive the at least one analog signal and convert the at least one analog signal to at least one digital signal to obtain measured data. A processing system includes one or more processors, the processing system configured for receiving the at least one digital signal. Memory is connected to the processing system. The processing system is configured to implement a self-describing database stored in the memory, the self-describing database including a first tier of information storing objects associated with the utility meter and a second tier of information storing metadata associated with the objects, the metadata including at least a data dictionary associated with one or more of the objects.

In certain implementations, a method of storing and retrieving data in a utility meter system includes implementing, by a processing system of the utility meter system, a self-describing database in a memory of the utility meter system, the self-describing database including a first tier of information storing objects associated with the utility meter and a second tier of information storing metadata associated with the objects, storing, in the first tier of information, objects including at least one of meter readings, meter information, and rate structure, and storing, in the second tier of information, metadata including a data dictionary associated with one or more of the objects, the data dictionary including information on each object's purpose, unit of measurement, valid ranges, and data types.

In certain configurations, a system for updating a utility meter includes a utility meter having a processing system, memory, and a communication interface, wherein the processing system is configured to receive a JavaScript Object Notation (JSON) file containing one or more configuration parameters via the communication interface, parse the JSON file to extract the one or more configuration parameters, validate the extracted configuration parameters to determine valid parameters and separate invalid parameters from the valid parameters, apply the valid parameters to update a configuration of the utility meter, and store the updated configuration in the memory.

In certain implementations, a method of updating a utility meter system includes creating a JavaScript Object Notation (JSON) file containing one or more configuration parameters for the utility meter, uploading the JSON file to the utility meter, parsing, by the utility meter, the JSON file to extract the one or more configuration parameters, validating the extracted configuration parameters to determine valid parameters and to separate invalid parameters from the valid parameters, applying the valid parameters to update a configuration of the utility meter, and storing the updated configuration in memory of the utility meter.

In certain configurations, a system for creating and distributing a firmware update file for a utility meter includes a plurality of utility meters configured to receive and implement an update file, and one or more processors executing a firmware update process configured to create the update file in a hex format containing one or more configuration parameters for one or more utility meters, convert the update file from the hex format to a binary format, divide the update file into a plurality of sections each containing a checksum and a data length, apply compression and encryption to the plurality of sections, create a file header including information about a target device for the firmware, a version, a build date, and a manifest, assemble the file header with the plurality of sections into a combined file, compute a checksum value for the combined file, and update the checksum value in the file header of the combined file, and a communication interface configured to transmit the combined file to the plurality of utility meters.

In certain implementations, a method of creating a distributable firmware update file for a utility meter includes creating an update file in a hex format containing one or more configuration parameters for one or more utility meters, converting the update file from the hex format to a binary format, dividing the update file into a plurality of sections each containing a checksum and a data length, applying compression and encryption to the plurality of sections, creating a file header containing information about a target device for the firmware, a version, a build date, and a manifest, assembling the file header with the plurality of sections into a combined file, computing a checksum value for the combined file, updating the checksum value in the file header of the combined file, and transmitting the combined file to a utility meter.

### BRIEF DESCRIPTION OF THE DRAWINGS

The aspects and features of various exemplary embodiments will be more apparent from the description of those exemplary embodiments taken with reference to the accompanying drawings.

FIG. 1 is a block diagram of an intelligent electronic device (IED).

FIG. 2 is a schematic diagram of a building automation system.

FIG. 3 is a schematic diagram of a BACnet communication stack.

FIG. 4 is a schematic diagram of a processor utilizing a dual virtual environment configuration to handle multiple communication protocols.

FIG. 5 is a schematic diagram of a processing system utilizing a virtual wrapper environment configuration to handle multiple communication protocols.

FIG. 6 is a schematic diagram of a self-describing database.

FIG. 7 is a flow chart showing a firmware upgrade using a JSON file.

FIG. 8 is a schematic view of a distributable firmware file.

FIG. 9 is a flow chart for creating a distributable firmware file.

### DETAILED DESCRIPTION OF EXEMPLARY EMBODIMENTS

In certain implementations, intelligent electronic devices (“IEDs”) sense electrical parameters and compute data and can be any device including, but not limited to, Programmable Logic Controllers (“PLC's”), Remote Terminal Units (“RTU's”), electric power meters, panel meters, protective relays, fault recorders, phase measurement units, serial switches, smart input/output devices and other devices which are coupled with power distribution networks to manage and control the distribution and consumption of electrical power. A meter is a device that records and measures power events, power quality, current, voltage waveforms, harmonics, transients and other power disturbances. Revenue accurate meters (“revenue meter”) relate to revenue accuracy electrical power metering devices with the ability to detect, monitor, report, quantify and communicate power quality information about the power that they are metering.

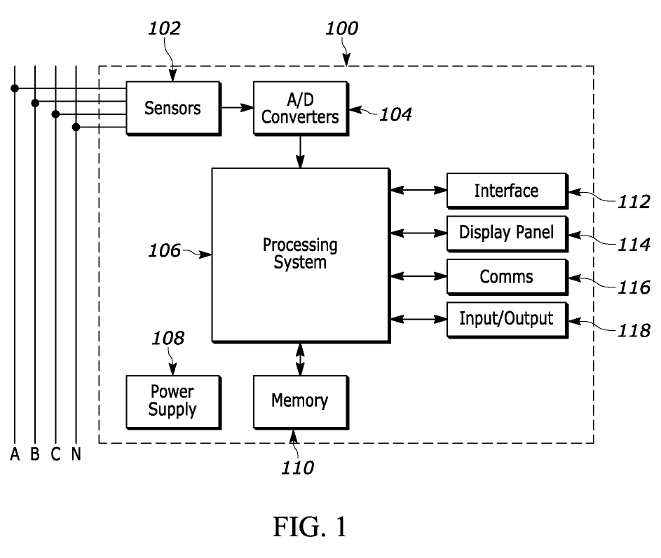

FIG. 1 shows an exemplary configuration of an IED 100 having a plurality of sensors 102 connected to various phases A, B, C and neutral N of an electrical distribution system. One or more analog-to-digital (A/D) converters 104 can be connected to the sensors and connect the sensors 102 to a processing system 106. The processing system 106 can include any combination of processing components including, a CPU, microcontroller, digital signal processors, field programmable gate arrays, programmable logic device, etc. The IED 100 can include a power supply 108 to supply power to the various components. One or more memory units 110 is connected to the processing system 106. The processing system 106 can be in communication with a user interface 112, a display panel 114, a communication interface 116, and one or more input/output ports 118.

The plurality of sensors 102 sense electrical parameters, e.g., voltage and current, on incoming lines, (i.e., phase A, phase B, phase C, neutral N), from an electrical power distribution system. In certain configurations, the sensors 102 can include current transformers and potential transformers, wherein one current transformer and one voltage transformer will be coupled to each phase of the incoming power lines. A primary winding of each transformer will be coupled to the incoming power lines and a secondary winding of each transformer will output a voltage representative of the sensed voltage and current.

The output of each transformer will be coupled to the A/D converters 104 configured to convert the analog output voltage from the transformer to a digital signal that can be processed by the processing system 106. A/D converters 104 are respectively configured to convert an analog voltage output to a digital signal that is transmitted to the processing system 106 to be processed. The processing system 106 is configured to operatively receive digital signals from the A/D converters 104 and to perform calculations necessary to determine power usage and to control the overall operations of the IED 100.

The power supply 108 provides power to each component of the IED 100. In certain configurations, the power supply 108 is a transformer with its primary windings coupled to the incoming power distribution lines and having windings to provide a nominal voltage, e.g., 5 VDC, +12 VDC and −12 VDC, at its secondary windings. In other configurations, power may be supplied from an independent power source to the power supply 108. For example, power may be supplied from a different electrical circuit or an uninterruptible power supply (UPS). In other configurations, the power supply can be a DC power supply such as a battery or rechargeable battery.

In some configurations, the power supply 108 can be a switch mode power supply in which the primary AC signal will be converted to a form of DC signal and then switched at high frequency, such as, for example, 100 Khz, and then brought through a transformer to step the primary voltage down to, for example, 5 Volts AC. A rectifier and a regulating circuit would then be used to regulate the voltage and provide a stable DC low voltage output. Other embodiments, such as, but not limited to, linear power supplies or capacitor dividing power supplies are also contemplated.

The IED 100 further comprises a memory unit 110 which can include one or more memory components, such as volatile memory and non-volatile memory. In addition to storing audio and/or video files, memory 110 can store the sensed and generated data for further processing and for retrieval when called upon to be displayed at the IED 100 or from a remote location. The memory 110 can include any combination of: internal storage memory, e.g., random access memory (RAM); removable memory such as magnetic storage memory; optical storage memory, e.g., the various types of CD and DVD media; solid-state storage memory, e.g., a CompactFlash card, a Memory Stick, SmartMedia card, MultiMediaCard (MMC), SD (Secure Digital) memory; or any other memory storage that exists currently or will exist in the future. By utilizing removable memory, an IED can be easily upgraded as needed. Such memory will be used for storing historical trends, waveform captures, event logs including time-stamps and stored digital samples for later downloading to a client application, web-server or PC application.

The user interface 112 is connected to the processing system 106 for interacting with a user and for communicating events, such as alarms and instructions to the user. The interface 112 may include any set of physical inputs, such as buttons, touch screens, dials, etc. The user interface 112 further includes a speaker or audible output means for audibly producing instructions, alarms, data, etc. The speaker is coupled to the processing system 106 via a digital-to-analog converter (D/A) for converting digital audio files stored in memory 110.

The IED 100 can also include a display 114 for providing visual indications to the user. The display may be embodied as a touch screen, a liquid crystal display (LCD), a plurality of LED number segments, individual light bulbs or any combination. The display 114 can provide information to the user in the form of alpha-numeric lines, computer-generated graphics, videos, animations, etc. In certain configurations, the IED 100 can also support various media file types.

In certain implementations, the IED 100 will include a communication device 116, also known as a network interface, for enabling communications between the IED or meter, and a remote terminal unit, programmable logic controller and other computing devices, microprocessors, a desktop computer, laptop computer, other meter modules, etc. The communication device 116 can be a modem, network interface card (NIC), wireless transceiver, etc. The communication device 116 will perform its functionality by hardwired and/or wireless connectivity. The hardwire connection may include but is not limited to hard wire cabling e.g., parallel or serial cables, RS232, RS485, USB cable, Firewire (1394 connectivity) cables, Ethernet, and the appropriate communication port configuration. The wireless connection will operate under any of the various wireless protocols including but not limited to Bluetooth™ interconnectivity, infrared connectivity, radio transmission connectivity including computer digital signal broadcasting and reception commonly referred to as Wi-Fi or 802.11.X (where x denotes the type of transmission), satellite transmission or any other type of communication protocols, communication architecture or systems currently existing or to be developed for wirelessly transmitting data including spread spectrum 900 MHz, or other frequencies, Zigbee, WiFi, or any mesh enabled wireless communication.

The IED 100 can communicate to a server or other computing device via the communication device 116. The IED 100 can be connected to a communications network, e.g., the Internet, by any means, for example, a hardwired or wireless connection, such as dial-up, hardwired, cable, DSL, satellite, cellular, PCS, wireless transmission (e.g., 802.11a/b/g), etc. It is to be appreciated that the network may be a local area network (LAN), wide area network (WAN), the Internet or any network that couples a plurality of computers to enable various modes of communication via network messages. Furthermore, the server will communicate using various protocols such as Transmission Control Protocol/Internet Protocol (TCP/IP), File Transfer Protocol (FTP), Hypertext Transfer Protocol (HTTP), etc. and secure protocols such as Hypertext Transfer Protocol Secure (HTTPS), Internet Protocol Security Protocol (IPSec), Point-to-Point Tunneling Protocol (PPTP), Secure Sockets Layer (SSL) Protocol, etc. The server will further include a storage medium for storing a database of instructional videos, operating manuals, etc., the details of which will be described in detail below.

In an additional configuration, the IED 100 can also have the capability of not only digitizing waveforms, but storing the waveform and transferring that data upstream to a central computer, e.g., a remote server, when an event occurs such as a voltage surge or sag or a current short circuit. This data will be triggered and captured on an event, stored to memory, e.g., non-volatile RAM, and additionally transferred to a host computer within the existing communication infrastructure either immediately in response to a request from a remote device or computer to receive said data in response to a polled request. The digitized waveform will also allow the processing system 106 to compute other electrical parameters such as harmonics, magnitudes, symmetrical components and phasor analysis. Using the harmonics, the IED 100 will also calculate dangerous heating conditions and can provide harmonic transformer derating based on harmonics found in the current waveform.

In a further configuration, the IED 100 can execute an e-mail client and will send e-mails to the utility or to the customer direct on an occasion that a power quality event occurs. This allows utility companies to dispatch crews to repair the condition. The data generated by the meters are used to diagnose the cause of the condition. The data is transferred through the infrastructure created by the electrical power distribution system. The email client will utilize a POP3 or other standard mail protocol. A user will program the outgoing mail server and email address into the meter.

The techniques of the present disclosure can be used to automatically maintain program data and provide field wide updates upon which IED firmware and/or software can be upgraded. An event command can be issued by a user, on a schedule or by digital communication that will trigger the IED 100 to access a remote server and obtain the new program code. This will ensure that program data will also be maintained allowing the user to be assured that all information is displayed identically on all units.

It is to be understood that the present disclosure may be implemented in various forms of hardware, software, firmware, special purpose processors, or a combination thereof. The IED 100 also includes an operating system and micro instruction code. The various processes and functions described herein may either be part of the micro instruction code or part of an application program (or a combination thereof) which is executed via the operating system.

It is to be further understood that because some of the constituent system components and method steps depicted in the accompanying figures may be implemented in software, or firmware, the actual connections between the system components (or the process steps) may differ depending upon the manner in which the present disclosure is programmed. Given the teachings of the present disclosure provided herein, one of ordinary skill in the related art will be able to contemplate these and similar implementations or configurations of the present disclosure.

The components and devices of the IED 100 can be positioned in various depending on the application or working environment. For example, the components can be positioned in a panel meter, socket meter, switchboard or draw-out type housing, A-base or type A housing. Other housings and mounting schemes are within the scope of this disclosure.

Additionally, the IED 100 can be implanted in various environments. For example, the IED 100 can be implemented in a network, such as public or private network, WAN, LAN, or other type of network. The IED 100 can be connected over the network to various other devices, such as through client/server networks, peer-to-peer networks, mesh networks, etc.

Examples of certain housings, environments, and other features that can be incorporated in the IED 100 are shown and described in U.S. Published Application 2020/0012488, the contents of which are hereby incorporated by reference in their entirety.

In certain implementations, the IED 100 can utilize the building Automation and Control Networks (BACnet) communication standard. Building automation systems have traditionally operated on proprietary communication protocols, creating significant integration challenges when connecting devices from different manufacturers or when expanding existing installations. The development of standardized communication protocols has addressed many of these challenges, with the BACnet protocol emerging as a predominant standard within the building automation industry.

The BACnet protocol provides a standardized framework for device communication across various building systems. This standardization ensures that devices from different manufacturers can effectively communicate and work together without requiring proprietary interfaces or gateways. This enables interoperability between devices regardless of manufacturer, significantly reducing integration complexity and enhancing system reliability.

BACnet supports seven different network types and physical media to connect devices, providing flexibility for various implementation requirements and existing infrastructure limitations. This adaptability has led to the protocol's widespread adoption, as it allows BACnet to be implemented in both new construction and retrofit applications across diverse building types. The most prevalent network types in modern BACnet implementations are BACnet/IP (Internet Protocol) and BACnet MS/TP (Master-Slave/Token-Passing), each offering distinct advantages for different application scenarios. Other supported network types include ARCNET, Ethernet, point-to-point communication over RS-232, and LonTalk, providing options for specialized applications or integration with legacy systems.

Certain implementations address the limitations of existing building automation communication implementations by providing systems and methods for smart utility metering utilizing an advanced BACnet protocol communication architecture. For example, certain configurations of an IED can be capable of communication over multiple physical transmission media, including both BACnet MS/TP over RS-485 and BACnet IP over Ethernet networks.

In one aspect, a utility metering system includes a plurality of utility meters configured to monitor resource consumption, wherein each meter implements native BACnet communication capabilities. The system further comprises a hierarchical network architecture supporting both BACnet MS/TP and BACnet IP communication pathways. This can provide significant advantages over prior implementations, including enhanced interoperability across device types, optimized bandwidth utilization, improved scalability, and unified management of meter data regardless of the underlying physical communication medium.

The utility metering system can implement a comprehensive BACnet communication architecture that enables interoperability between metering devices across different physical media. The system architecture, as illustrated in FIG. 1, comprises multiple hierarchical levels, including field-level devices, control-level components, and management-level interfaces.

At the field level, utility meters are equipped with native BACnet communication capabilities utilizing both the MS/TP or IP variant of the protocol. Each meter represents a collection of standardized BACnet objects that encapsulate various metering parameters including power consumption, voltage levels, current readings, and cumulative energy usage. The object-oriented representation provides a uniform mechanism for accessing meter data regardless of the specific hardware implementation.

The BACnet MS/TP implementation can operate over EIA-485 electrical signaling, utilizing a shared bus architecture with daisy-chained devices. The implementation addresses several critical aspects that affect communication reliability and performance in metering applications.

The MS/TP protocol implements a master-slave architecture regulated by a token-passing mechanism. Utility meters may function as either master devices capable of initiating communication or slave devices that respond only when addressed. Master devices participate in token rotation, with each device holding the token for a configurable duration before passing it to the next master in sequence. This deterministic access method prevents data collisions that might otherwise compromise metering accuracy.

The meter can implement an optimized token passing algorithm that prioritizes devices based on their reporting frequency requirements, ensuring that meters monitoring critical loads receive more frequent communication opportunities. The token passing sequence is dynamically adjusted based on observed network traffic patterns, with token hold times calibrated to prevent any single device from monopolizing the communication medium.

The BACnet IP implementation utilizes Internet Protocol (IP) networks for building automation communications, which allows BACnet devices to communicate over standard Ethernet infrastructure. This approach facilitates integration with enterprise networks and enables remote access capabilities, aligning building automation systems with modern IT infrastructure. BACnet/IP uses the User Datagram Protocol (UDP) for data transmission, employing a client-server communication model where devices typically act as servers. BACnet/IP packets consist of two primary components: an immutable part that includes the BACnet Virtual Link Control (BVLC) type, BVLC function, and length, and a variable part that changes according to the BVLC Function. The Network Layer Protocol Data Unit (NPDU) forms the core of the BACnet/IP message structure, encapsulating the application layer data and routing information necessary for proper network communication.

The processing system 106 can be configured to handle both the MSTP and the IP communications utilizing two separate virtual environments with one handling the MSTP stack and the other handling the IP stack. In certain configurations, this can be achieved using a single processor with multithreading at the OS kernel level.

For example, a single processor may be running an OS kernel in the processing system 106. The system can contain two separate libraries, one utilizing the MSTP communication stack and the other utilizing the IP stack. The communication can be transferred to both libraries simultaneously or nearly-simultaneously. A near simultaneous transfer can include utilizing both execution paths through timesharing, for example, when used with a single-core processor. Different operating system kernels can employ various threading models to handle network processing in a multithreading process. When a BACnet communication is received, the communication can be passed to the MSTP library and the IP library using multithreading. Each library will be tied to the respective communication channel.

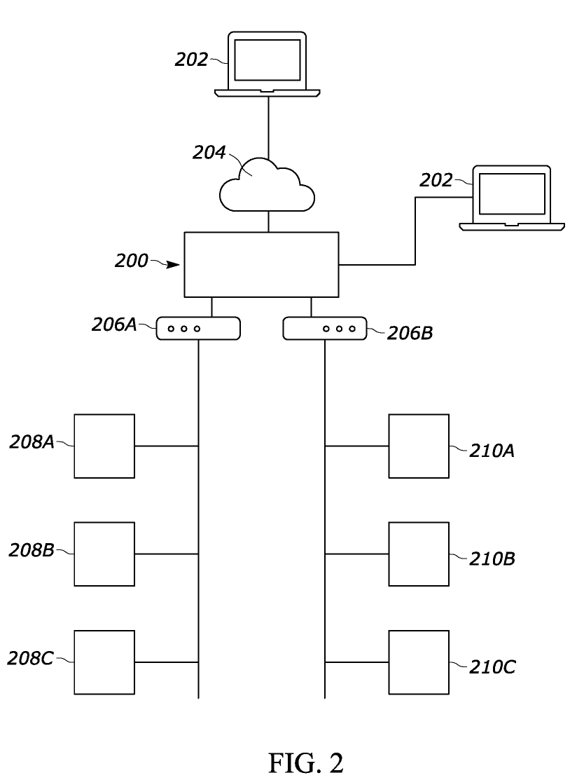

FIG. 2 shows an exemplary configuration of a building automation system 200. One or more client devices 202 can be connected to the building automation system, either directly through a local connection or through a network such as the Internet 204. The system can include one or more BACnet communication devices, for example a first BACnet communication device 206A and a second BACnet communication device 206B. The BACnet communication devices 206A, 206B can be configured to communicate with devices over a specific communication protocol and can include controllers, routers, or other similar devices.

The first BACnet communication device 206A is connected to a plurality of downstream building devices 208A-C. The second BACnet communication device 206B is connected to a plurality of downstream building devices 210A-C. In an exemplary configuration, the first BACnet communication device 206A can be configured to communicate via the BACnet IP protocol and the second BACnet communication device 206B can be configured to communicate via the BACnet MSTP protocol. Various configurations of such systems can be found, including systems that use only a single communication protocol. Accordingly, it is advantageous to provide communication over more than one protocol with a single device without having to reconfigure the device or use a separate router. This can allow a device to be used with flexibility in a variety of systems.

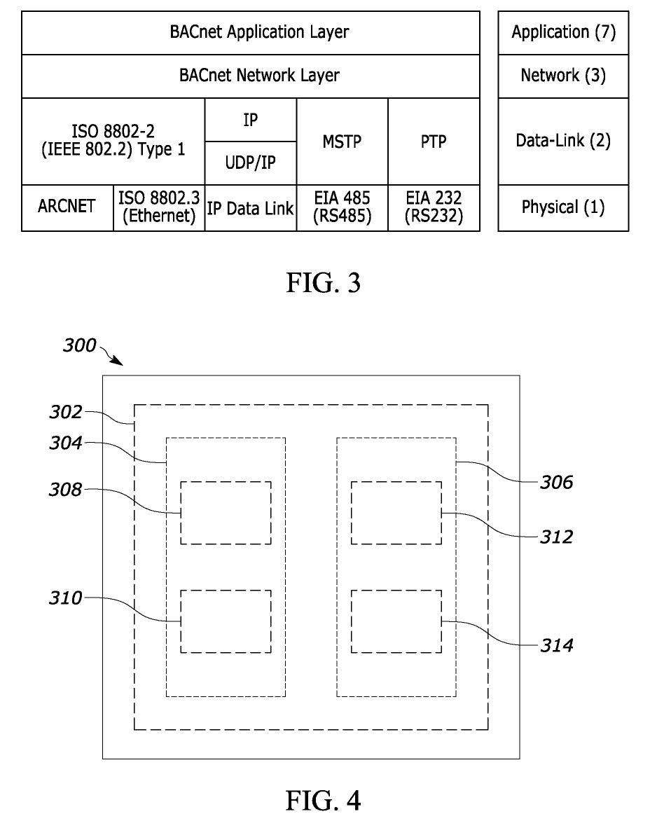

FIG. 3 shows an exemplary configuration of a BACnet communication protocol stack. When using different protocols, the network layer and application specifications can be different.

FIG. 4 shows an exemplary configuration of a processor 300 that can be in the processing system 106. The processor can include an operating system kernel 302. The kernel 302 can include a first environment 304 and a second environment 306. The first environment 304 can include a first communication protocol 308, for example a first BACnet protocol stack and a first library 310. The second environment 306 can include a second communication protocol 312, for example a second BACnet protocol stack and a second library 314. Other files, such as configuration files, can also be included in each environment 304, 306.

The first library 310 can provide the necessary files to implement a first version of the BACnet protocol stack. For example, the first library 310 can provide the necessary files to implement the BACnet MSTP protocol. The second library 314 can provide the necessary files to implement a second version of the BACnet protocol stack. For example, the second library 314 can provide the necessary files to implement the BACnet IP protocol.

The kernel 302 can multithread communications to both environments. Because the IP stack will not recognize MSTP communications and vice versa, the kernel 302 will provide a single output for communications as needed. In this way, each of the environments 304, 306 can manage its own threads for sending, receiving, and processing communications. The single processor 300 can therefore handle multiple types of communications without additional components or reprogramming. Different processing and scheduling methods can be used to appropriately handle the data and sharing of resources.

In certain embodiments, the system may include a BACnet library that is specifically configured to allow the system to communicate in both the BACnet MS/TP protocol and the BACnet IP protocol. While such configuration is advantageous in that a single library allows the system to interact with devices that only communicate using a single protocol (i.e., BACnet IP or BACnet MS/TP), a problem arises in certain versions of the BACnet library, in which the system is unable to perform communications using the BACnet MS/TP protocol (but is still able to communicate using the BACnet IP protocol).

Such problem may be the result of having global variables that are present by default in certain versions of the BACnet library. More specifically, because the global variables are used for communications under both the BACnet MS/TP protocol and the BACnet IP protocol, modifications to the global variables that are made during communications in one protocol may adversely affect communications made under the other protocol, as both the BACnet MS/TP protocol and the BACnet IP protocol share the same global variables. For example, such modifications may occur during reentrancy in which a first process is interrupted by a second process (for example) and then resumed. In between, the second process may modify a global variable that is already in use by the first process, thereby causing errors after the first process resumes execution.

Consequently, while the BACnet library is notionally able to provide services under the BACnet MS/TP protocol and the BACnet IP protocol, in practice, a device using such BACnet library is limited to communicating under only one protocol.

One possible solution to the aforementioned problem involves a system that can utilize a UDP/IP communications subsystem and a wrapper subsystem, wherein the wrapper subsystem embeds compiled BACnet MS/TP code while maintaining operational concealment of the MS/TP implementation from the UDP/IP communications subsystem.

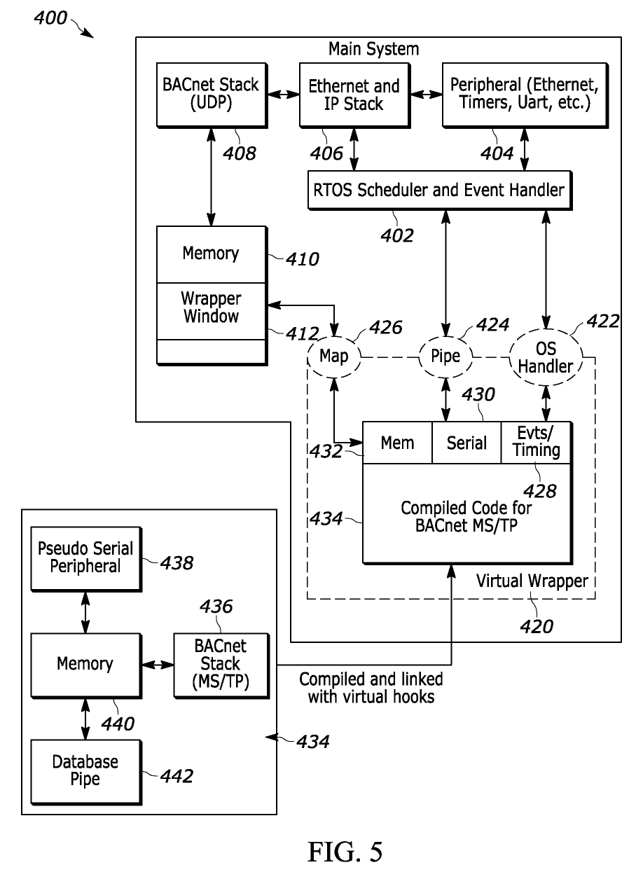

FIG. 5 shows an exemplary configuration of a main system 400 configured to execute BACnet communications over UDP while additionally hosting a BACnet MS/TP communications capability that is operatively concealed behind a wrapper.

An RTOS scheduler and event handler 402 is provided and can be configured to schedule execution, convey messages, and deliver events within the system. In operation, the RTOS scheduler and event handler 402 can provide a common scheduling and message-delivery framework for both the UDP/IP BACnet path and the wrapped MS/TP path, such that each path can receive requests and provide responses using the same system-level eventing and timing mechanisms. A peripheral input block 404 is provided for interfacing to physical peripherals including Ethernet, timers, and UART resources. An Ethernet and IP stack 406 is provided for network-layer and link-layer services supporting UDP communications. A BACnet stack (UDP) 408 is provided for UDP-based BACnet message processing. In certain implementations, the BACnet stack 408 may be or include the BACnet library which, as was previously discussed, allows a system (e.g., main system 400) to communicate using both the BACnet MS/TP protocol and the BACnet IP protocol.

A memory block 410 is provided. In certain configurations, a wrapper window memory 412 can be further provided. The wrapper window 412 can define a constrained memory region associated with wrapper operation. In certain embodiments, the wrapper window memory 412 is implemented as a reserved physical partition protected by a memory protection mechanism, such that access permissions may be constrained to a predefined region and thereby prevent unrestricted access outside the wrapper window. Similar results may also be achieved utilizing a virtual partition.

A wrapper 420 is provided and is configured to mediate interactions between the main UDP/IP BACnet portion and the internally hosted BACnet MS/TP portion. In certain implementations, the wrapper 420 allows for the access of functionality (e.g., function, procedure, method, subroutine, routine, or subprogram) in compiled code, while simultaneously concealing the structure (e.g., local and/or global variables) and one or more functionalities included in the compiled code. The wrapper can include a plurality of wrapper components, including an OS handler 422, a pipe component 424, and a map component 426.

The OS handler 422 is configured as a virtualization layer that presents OS-like services to the internally hosted MS/TP compiled code. In operation, the OS handler 422 exposes virtualized service entry points corresponding to at least memory services, serial services, and event/timing services. By way of such virtualized services, the MS/TP compiled code can request OS-dependent functionality without requiring direct access to the underlying system OS primitives, and without requiring the MS/TP code to be aware of the UDP/IP BACnet stack.

The pipe component 424 is configured to convey data between the RTOS scheduler and event handler 402 and the wrapper, and further to convey data between the wrapper and the internally hosted MS/TP functionality. In operation, the pipe component 424 acts as a controlled conduit such that requests delivered under RTOS control can be forwarded into the wrapper environment and responses can be returned through the same conduit, while maintaining separation between the UDP/IP BACnet stack 408 and the MS/TP compiled code.

The map component 426 is configured to provide a controlled interface into memory, including a limited window of access associated with the wrapper window memory 412. In operation, the map component 426 defines what subset of memory and what structures are visible to the wrapper and/or to the MS/TP compiled code, thereby supporting separation between the two communications subsystems by limiting shared-memory visibility to a deliberate interface region rather than permitting unrestricted access to system memory 410.

The events/timing block 428 is configured to provide event and timing functionality used by the wrapper and by the virtualized MS/TP environment. In operation, events and timing services provided by block 428 are used to support scheduling, retries, token-related timing behavior, and general time-based execution within the wrapped MS/TP subsystem, while remaining coordinated with the RTOS scheduler and event handler 402.

The serial communication component 430 is configured to provide serial communication support used by the wrapper and by the MS/TP compiled code via virtualization, including supporting a serial-oriented interface model expected by the MS/TP stack. In operation, the serial communication component 430 cooperates with the OS handler 422 such that serial I/O operations requested by the MS/TP compiled code are serviced by wrapper-controlled mechanisms rather than by direct access to physical UART resources, thereby assisting in concealment and isolation.

A wrapper memory block 432 is provided and is configured as a memory-resident wrapper presence supporting the foregoing isolation and mediation functions. In operation, the wrapper memory block 432 may be understood as the portion of the wrapper that is placed within, or otherwise associated with, the constrained wrapper window memory so as to support the controlled interface model implemented by the map component 426 and the pipe component 424. The wrapper memory block 432 can cooperate with the map component 426 to maintain the limited memory access model and to support isolation of the embedded compiled MS/TP subsystem from the UDP/IP subsystem.

A compiled code block 434 is provided for BACnet MS/TP. In certain implementations, the compiled code block 434 comprises compiled code, which may be a binary or executable program (e.g., generated by compiling source code) that includes one or more sets of instructions executable by a processor (e.g., processor 300). The compiled code includes a BACnet stack (MS/TP) 436. A pseudo serial peripheral 438 is provided. An internal memory 440 is provided. A database pipe 442 is provided.

In certain implementations, the BACnet stack 436 may be or include the BACnet library which, as previously discussed, allows a system (e.g., main system 400) to communicate using both the BACnet MS/TP protocol and the BACnet IP protocol. In one example, the BACnet library in the BACnet stack 436 is the same (i.e., a duplicate) as the BACnet library included in the BACnet stack 408. In another example, the BACnet library included in the BACnet stack 408 may be modified to include functionality only for communications under the BACnet IP protocol. In yet another example, the BACnet library included in the BACnet stack 436 may be modified to include functionality only for communications under the BACnet MS/TP protocol.

In operation, the pseudo serial peripheral 438 is configured to emulate a serial device interface to the BACnet stack (MS/TP) 436, such that the MS/TP stack can perform serial-interface operations against a virtualized serial endpoint rather than requiring a physical serial peripheral dedicated to that stack. The serial communication component 430, operating under wrapper control, cooperates with the pseudo serial peripheral 438 such that serial read/write semantics invoked by the MS/TP stack are mediated within the wrapper environment.

The database pipe 442 is configured to support access by the internal MS/TP code to system database objects through wrapper-mediated mechanisms. In operation, the database pipe 442 may be implemented in different modes, including as a remapper, as a request/reply queue mechanism, and/or as an object translator, to thereby support controlled and minimally atomic access on a per-object basis by the internal BACnet MS/TP stack to the system database, while maintaining separation from the main UDP/IP BACnet subsystem.

The code block 434 can be compiled and/or embedded in the wrapper with virtual hooks. In one implementation, such virtual hooks are realized through a vector call table comprising a plurality of function pointers, wherein each function pointer corresponds to a service provided by the compiled code . The main system 400 may access the functionality or service provided by the BACnet library included in the compiled code via the vector call table.

In operation, when the system 400 receives instructions to communicate using a communication protocol, the system 400 determines whether the communication protocol corresponds to a BACnet IP protocol or a BACnet MS/TP protocol. In case that the communication protocol corresponds to a BACnet IP protocol, the system 400 directly accesses and executes the services provided by the BACnet library in the BACnet stack 408. In case that the communication protocol corresponds to BACnet MS/TP protocol, the system 400 accesses one or more functionalities in the BACnet library of the compiled code via calls through the vector call table, thereby invoking wrapper-provided service implementations. Then, the system 400 executes the one or more functionalities in the BACnet library of the compiled code to communicate using BACnet MS/TP protocol.

This configuration permits the compiled code to be inserted into or accessible by the main system while remaining operatively isolated, because external dependencies (including memory services, serial services, and event/timing services) are resolved by function-pointer binding to wrapper components including the OS handler 422, the serial communication component 430, and the events/timing block 428.

More specifically, the wrapper 420 conceals the structure including the local and global variables that are present in the BACnet library of the compiled code (e.g., a black box), while allowing functionality of the BACnet library (e.g., for performing communications under the MS/TP protocol) of the compiled code to be accessed via the vector call table. As a result of this configuration, the global variables in the BACnet library in the BACnet stack 408 have no (negative) impact when the main system 400 performs communications under the MS/TP protocol. For example, one or more modifications (e.g., during reentrancy, as described previously) to at least one specific global variable in the BACnet library of the BACnet stack 408 are not reflected in a corresponding global variable in the BACnet library of the compiled code and vice versa.

In addition, because the BACnet library in the BACnet stack 408 is separated from the BACnet library in the BACnet stack 436 (which is operatively concealed), the global variables in the BACnet library in the BACnet stack 408 are not affected when communications are made under the MS/TP protocol and the global variables in the BACnet library in the compiled code are similarly not affected when communications are made under the IP protocol.

For example, at the time the compiled MS/TP code block 434 is embedded in the wrapper, the vector call table can be populated with addresses of wrapper-provided and embedded-service-provided functions such that the compiled MS/TP code block is operatively bound to the wrapper environment. In particular, vector call table entries corresponding to event and timing services are bound to event and timing functionality associated with block 428, entries corresponding to serial communication services are bound to serial communication functionality associated with block 430 and the pseudo serial peripheral 438, and entries corresponding to memory and interface services are bound to wrapper-defined access mechanisms including the map component 426 and the wrapper window memory 412.

In certain configurations, the vector call table can include functional pointer entries that relate to one or more categories configured to map the compiled MS/TP code’s external dependency to wrapper-controlled functions. These categories can include memory management (e.g., allocation/deallocation of buffers), serial communication (e.g., read/write semantics), events and timing (e.g., timer start/expiry signaling), database access (e.g., object read/write), and error reporting (e.g., fault reporting/logging).

Accordingly, the virtual hooks and vector call table arrangement permits the compiled code block 434 to execute within the wrapper as an embedded compiled subsystem while external interactions of said subsystem are constrained to the wrapper-defined interfaces, thereby concealing MS/TP implementation details from the UDP/IP subsystem and preventing direct coupling between the BACnet stack (UDP) 408 and the BACnet stack (MS/TP) 436.

In operation, the BACnet stack (UDP) 408 processes BACnet application layer messages for UDP transport and calls into the Ethernet and IP stack 406 to send and receive UDP packets. The wrapper 420 is configured to receive, in parallel, message data or request data associated with BACnet operations, wherein the wrapper is configured to forward applicable requests into the embedded MS/TP subsystem through the pipe component 424, and to return response data from the embedded MS/TP subsystem outward through the pipe component 424.

In certain implementations, the processing system 106 is configured to provide more efficient write and retrieval of information stored in the memory. This information can include meter readings as well as configuration data. Typically information had to be stored in a table based on the Modbus format. This could require multiple look-up tables to determine the relationship between the memory locations and the saved data. For example, a display screen layout can include a first look-up table associating the defined data in the screen placeholders with a register of a Modbus map. A second look-up table is also stored in memory which associates the Modbus registers with locations in the memory where measured and calculated data are stored. In operation, as a screen layout is displayed, the processor of the meter will read the data defined in the placeholder of the screen layout and use this information to determine the associated Modbus register from the first look-up table. The processor then employs the second look-up table to determine the location in memory, e.g., RAM, flash, etc., of the desired data based on the Modbus register. The Modbus map that defines what the data is (e.g., voltage readings, current readings, etc.), where the data is stored (e.g., data addresses), and how the data is stored (data types, byte and word ordering) in the meter, in accordance with the Modbus protocol. This configuration of data storage can lead to even further complications for compatibility when using other communication protocols.

To simplify data storage and retrieval, the processing system 106 can implement a self-describing database. Use of a self-describing database can allow any protocol to access data and streamline the internal access of data for the IED 100. The self-describing database can store objects and metadata about the objects. For example, these can include values along with other information such as units, relationship to measured parameters (i.e., current or voltage), storage format, etc. The self-describing database can also contain access information that defines users that can read and write specific data entries, giving greater flexibility to access and management of the data stored by the IED 100.

Examples of metadata that can be associated with each object include: data types that determine what kind of information can be entered into specific fields; relationship definitions that establish connections between tables; constraints that enforce data uniqueness and prevent duplicate entries; access privileges that control read and write capabilities for different users; and descriptive information about the nature and purpose of data elements.

Whereas typical Modbus data entries utilize a register-based data model, the self-describing database can employ complex relational or object-oriented structures with comprehensive metadata. The self-describing database can also support query languages, such as SQL, that can lead to more efficient retrieval of information and the ability to compile and compare complex related data.

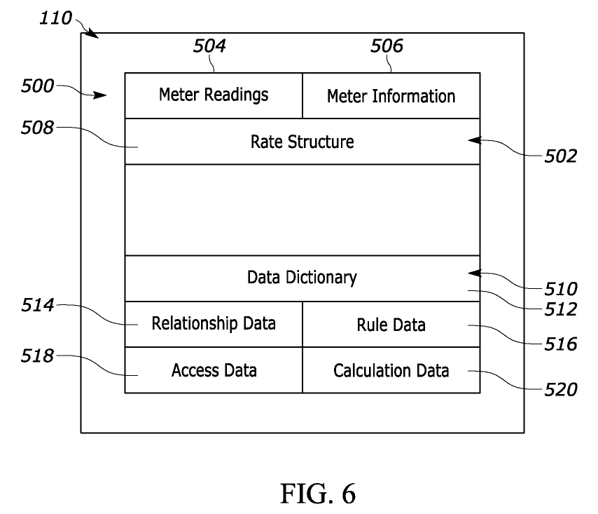

FIG. 6 shows an example of an architecture for the self-describing database for the IED 100 implemented as an electrical utility meter. The database 500 can be incorporated into the one or more memory units 110 stored locally in the IED 100. The database 500 can include a first tier of information 502 storing objects or values. This can include meter readings 504 (i.e., energy/power readings), meter information 506 (i.e., identification number, model, installation date, firmware version, location, etc.), and rate structure 508 (i.e., rate plans, time periods, pricing tiers, etc.). The database 500 also includes a second tier of information 510 storing metadata about the each of the objects in the first tier 502 as appropriate. This metadata can include a data dictionary 512 that includes, for example, information on each object’s purpose, unit of measurement, valid ranges, and data types. Relationship data 514 can define various relationships between objects. Rules 516 can define specific constraints for valid object data. Access data 518 can define who has access to what data. Calculation data 520 can provide formulas used to calculate values for specific data. Accordingly, each object in the first tier 502 can have one or more of the metadata categories in the second tier 510.

The database 500 can provide for query-based retrieval of information, allowing a user to formulate SQL or other text based queries to extract specific data based on complex criteria such as time periods, consumption rates, or locations. Predefined template reports can also more easily be generated than with standard Modbus tables. The templates can leverage the metadata to generate standard reports, such as billing or operational reports.

In certain implementations the IED 100 can be configured using JavaScript Object Notation (JSON) files. For example, firmware updates can be pushed to the IED using JSON files. JSON files serve as the intermediary between users and meter hardware, allowing for standardized communication that is both machine-processable and human-understandable. The IED 100 can be configured entirely through these files, eliminating the need for proprietary software tools or complex programming interfaces, which allows for a human readable format in providing programming updates and in retrieving meter information.

The JSON files can group features and updates together. For example, a JSON file can be used to configure the Modbus protocol in the IED 100 and a second JSON file can be used to configure the connection information or type of the IED 100. This can allow selective updates to be applied to certain system. This separation allows for focused configuration of specific functionality, reduced complexity when updating individual features, better organization of related parameters, and simplified troubleshooting of configuration issues.

Using JSON files can also allow devices with older firmware to receive updates. JSON files can implement updates on systems or firmware with familiar variables, allowing devices to ignore parameters, settings, or other data that is unknown. For example, with a meter supporting the Modbus protocol, the JSON file can include specific mapping between JSON keywords and specific Modbus registers. This allows configuration files to include newer parameters without breaking compatibility with older firmware.

A user can also retrieve current configuration from the IED 100 in JSON format. This can allow for a user to view current settings, create templates for new configurations, verify applied configurations, and backup meter settings. In certain implementations, when a configuration is retrieved, the meter generates a complete JSON file containing all parameters and settings it supports, providing a comprehensive view of the meter's capabilities and current configuration.

Information retrieval can also include security parameters that mask certain information, for example using a string of asterisk instead of the actual characters, based on a user’s access level. The JSON configuration can incorporate these security measures to protect sensitive information. When configuration files are retrieved from meters, any security-related parameters (such as passwords, access tokens, or encryption keys) can be automatically masked. The structure of the JSON remains intact but with sensitive information hidden. This prevents unauthorized access to security credentials while allowing the rest of the configuration to be viewed.

For example, an information retrieval process can include a user connecting to a device to request configuration information. The device can compile the information which can include all supported parameters. The values for each parameter can be accessed, for example from memory locations, and applied to the report. Any secure parameters can be masked. The completed JSON file can then be returned to a user.

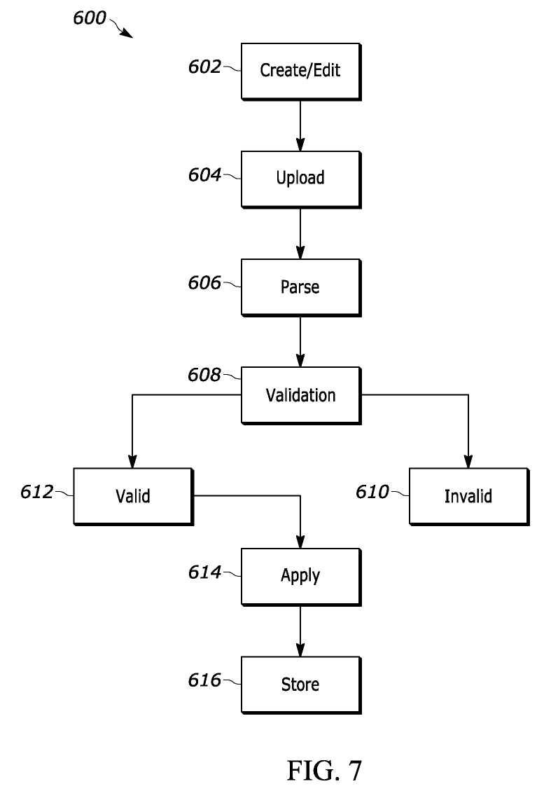

FIG. 7 shows an exemplary process of updating a utility meter utilizing a JSON file 600. The JSON file is created or edited 602 by a user. The file is then uploaded 604 to a device, such as IED 100. The device parses the JSON file 606 to extract configuration parameters. The device validates 608 the structures and the values of the parameters to separate out invalid parameters 610 from valid parameters 612. Invalid parameters 610 can be those that are not recognized or applicable to the device. The device can then apply the valid parameters 614 to update the appropriate configurations. The device can then store 616 the new configuration in the memory.

Use of the JSON file configuration can provide a more flexible and user-friendly approach to configuration and management of one or more IEDs. By utilizing structured JSON files, the system enables efficient configuration while maintaining backward compatibility and security.

Additional anti-tamper security and authentication procedures can be included in firmware updates. In certain implementations, after the firmware update has been created it can be scrambled, encrypted, zipped, signed, and wrapped around a container before being saved as a distributable firmware package. An encryption signature can be used to sign the package with a private key only available to the appropriate developers. When an upgrade is needed, a file can be uploaded into the IED 100 and the IED 100 can perform the reverse action starting by verifying the signature with a public key. Only after all this reversion the meter will have the real firmware in it and use it to upgrade itself. This prevents firmware tampering or the use of non-original firmware for the meter.

For example, a digital signature algorithm, such as, but not limited to, Elliptic Curve Digital Signature Algorithm (ECDSA) may be used to ensure the authenticity of a decrypted package. Digital signature algorithms may use a private and public key to generate and verify digital signatures. This allows a digital signature to be verified without querying a server for authentication information, preventing man-in-the-middle attacks on the signature verification process. For example, a public key is generated and stored in the IED 100, where the public key is generated by a private key known to the creator of the package updates. The private key is then used to generate a digital signature which is stored in the header of the decrypted package. The public key and a digital signature algorithm (e.g., ECDSA) may then be used by the IED 100 to verify the digital signature in the header of the decrypted package for authenticity. The digital signature can only be computed with access to a private key, only know by the generator (or creator) of the packages ensuring the authenticity of the decrypted package.

The key, digital signature algorithm and/or other encryption algorithms may be stored on the IED in a layer, module or memory that is not accessible externally via a communications software. For example, in one embodiment, the key, digital signature algorithm and/or other encryption algorithms may be stored on a separate CPU/DSP/FPGA than those shown in figures described in relation to the above embodiments. In a further embodiment, the key, digital signature algorithm and/or other encryption algorithms may be stored on a dedicated encryption chip. Similar techniques for providing security of the key, digital signature algorithm and/or other encryption algorithms is described in commonly owned U.S. application Ser. No. 14/742,061, the contents of which are incorporated by reference in its entirety.

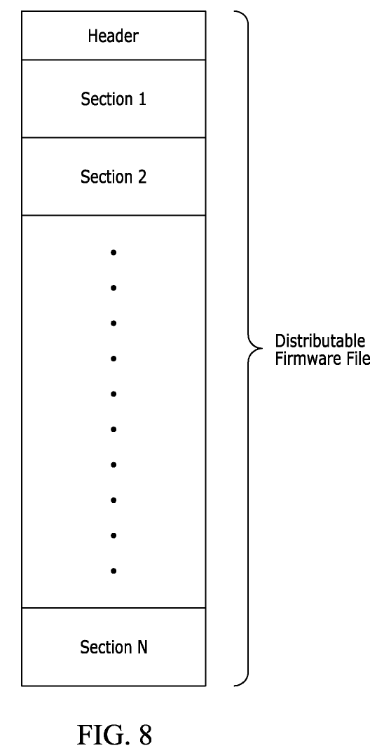

In certain implementations the firmware upgrade file is divided into small sections as shown in FIG. 8. Each section can contain its checksum and data length and one common header. These sections also implement encryption and compression.

There can be an initial block called the file header, which contains general information about the target device for the firmware, the version, build date, manifest, and other public information needed for the firmware upgrade process. The file header helps the software and the device to understand more about the file which is to be transmitted through communication medium and verified by the device, assuring integrity and security.

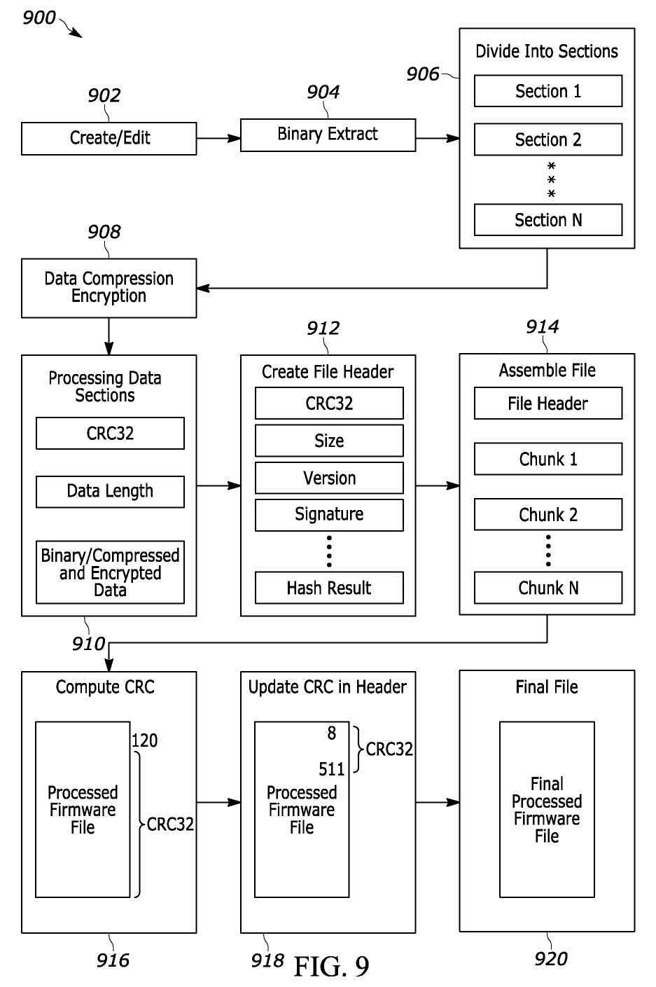

FIG. 9 shows a schematic view of a process 900 for creating a distributable firmware file for one or more utility meters, such as IED 100. The process 900 illustrates the sequential transformation of a firmware update from an initial hex file through a series of processing stages to produce a final processed firmware file suitable for distribution to and installation on one or more utility meters.

At an initial stage 902, a firmware update file is created or edited as a hex file. The hex file contains one or more configuration parameters for one or more utility meters. The hex file may be created or edited by a user, such as a firmware developer or authorized personnel, using tools appropriate for the target device. The hex file serves as the starting point for the firmware update process and represents the firmware in a hex format prior to any further processing.

At a next stage 904, the hex file is converted from the hex format to a binary format by a binary extract operation. The binary extract operation reads the hex file and produces a binary representation of the firmware data. This conversion prepares the firmware data for subsequent division and processing by translating the hex-encoded content into a binary format suitable for sectioning.

At stage 906, the binary file is divided into a plurality of sections. As depicted in FIG. 9, the division produces a plurality of sections, including a Section 1, a Section 2, and continuing through a Section N, where N represents the total number of sections into which the firmware file is divided. Each section contains a checksum and a data length. The division of the firmware file into multiple sections facilitates the subsequent per-section application of compression and encryption, and permits the firmware update to be transmitted and verified on a section-by-section basis.

At stage 908, each of the plurality of sections undergoes data compression and encryption. The data compression and encryption operation can be applied to each section individually, such that each section is independently compressed and then encrypted. The compression reduces the size of each section for more efficient transmission over a communication interface, and the encryption secures the firmware data within each section against unauthorized access or tampering.

At stage 910, the compressed and encrypted sections are further processed into data sections, referred to in FIG. 9 as "Processing Data Sections." During this processing, an integrity check can be added and the data sections are processed into chunks. As depicted in FIG. 9, each processed section includes one or more chunks, for example Chunk 1, Chunk 2, through Chunk N. Each chunk includes binary, compressed, and encrypted data together with an associated CRC32 checksum value. The CRC32 checksum associated with each chunk provides a per-chunk integrity verification mechanism, allowing the receiving utility meter to verify the integrity of each chunk individually.

At stage 912, a file header is created. As shown in FIG. 9, the file header includes general information about the target device for the firmware, including a file header field, a CRC32 field, a size field, a version field, a data length field, a signature field, and a hash result field. The file header contains information about the target device for the firmware, the version, a build date, and a manifest, as well as other public information needed for the firmware upgrade process. The file header helps both the software used to manage the firmware distribution and the target utility meter to understand the contents and characteristics of the file that is to be transmitted through a communication medium and verified by the device, thereby assuring integrity and security.

At stage 914, the file header is assembled with the plurality of processed sections into a combined file, referred to in FIG. 9 as the "Assemble File" stage. The assembly operation produces a single combined file in which the file header precedes the plurality of processed data sections. This combined file constitutes the assembled firmware update file prior to final integrity computation.

At stage 916, a checksum value is computed for the combined file. As depicted in FIG. 9, this stage is labeled "Compute CRC" and produces a CRC value that reflects the integrity of the entire combined file, including the file header and all processed data sections. In certain implementations, the checksum value computed for the combined file is a cyclic redundancy check (CRC) value. The computation of the CRC at this stage provides an overall integrity verification for the distributable firmware file as a whole.

At stage 918, the computed CRC value is updated in the file header of the combined file. As shown in FIG. 9, this stage is labeled "Update CRC In Header." By writing the computed CRC value back into the file header, the combined file becomes self-verifying: a receiving utility meter or intermediate software can read the CRC value from the file header and recompute the CRC over the file contents to confirm that the file has not been corrupted or altered during transmission.

At stage 920, the final processed firmware file is produced. As depicted in FIG. 9, this stage is labeled "Final File" and represents the completed distributable firmware file ready for transmission to one or more utility meters. The final file may receive a specific file extension identifying the combined file as intended for a specific device type, such as a utility meter. The final processed firmware file may then be transmitted to the one or more utility meters via a communication interface.

In certain implementations, the combined file may be further signed with a digital signature using a private key, and the signed combined file may be wrapped in a container to produce a distributable firmware package. The digital signature may be generated using a digital signature algorithm, such as the Elliptic Curve Digital Signature Algorithm (ECDSA). Upon receipt of the distributable firmware package, the utility meter may verify the digital signature using a public key stored in the utility meter and the digital signature algorithm. In certain configurations, the public key and the digital signature algorithm are stored on the utility meter in a layer, module, or memory that is not accessible externally via communications software, thereby preventing unauthorized verification bypass or tampering with the signature verification process.

The file header, as depicted in FIG. 9, is configured to allow software and a respective utility meter to verify the integrity and security of the combined file prior to applying the firmware update. The signature field and hash result field included in the file header support authentication of the firmware file, while the CRC32 field and size field support verification that the file has been received completely and without corruption. In this manner, the distributable firmware file produced by the process 900 incorporates multiple layers of integrity and security verification, including per-chunk CRC32 checksums, an overall file CRC, and, in certain implementations, a digital signature, to ensure that only authentic and unaltered firmware is applied to the utility meter.

The foregoing detailed description has been provided for the purpose of explaining the general principles and practical application, thereby enabling others skilled in the art to understand the disclosure for various configurations and implementations, and with various modifications as are suited to the particular uses contemplated. This description is not necessarily intended to be exhaustive or to limit the disclosure to what is disclosed. Any of the configurations and/or elements disclosed herein may be combined with one another to form various additional embodiments not specifically disclosed. Accordingly, additional configurations and implementations are possible and are intended to be encompassed within this specification and the scope of the appended claims. The specification describes specific examples to accomplish a more general goal that may be accomplished in another way.

As used in this application, the terms “front,” “rear,” “upper,” “lower,” “upwardly,” “downwardly,” and other orientational descriptors are intended to facilitate the description of the exemplary embodiments of the present disclosure, and are not intended to limit the structure of the exemplary embodiments of the present disclosure to any particular position or orientation. Terms of degree, such as “substantially” or “approximately” are understood by those of ordinary skill to refer to reasonable ranges outside of the given value, for example, general tolerances associated with manufacturing, assembly, and use of the described embodiments. Unless specified or limited otherwise, the terms “mounted,” “connected,” “supported,” and “coupled” and variations thereof are used broadly and encompass both direct and indirect mountings, connections, supports, and couplings. The words “member,” “component,” “module,” “mechanism,” “element,” “device,” and the like are not a substitute for the word “means.” As such, no claim element should be construed as a means plus function unless the element is expressly recited using the phrase “means for.”

Functionality described herein may be implemented by any combination of hardware, software, or firmware. Functionality described herein as being performed by one component may be performed by multiple components in a distributed manner. Likewise, functionality performed by multiple components may be consolidated and performed by a single component. Similarly, a component described as performing particular functionality may also perform additional functionality not described herein. For example, a device or structure that is “configured” in a certain way is configured in at least that way but may also be configured in ways that are not explicitly listed.

Certain electrical components are generally shown and described in terms of their functions or end results as it would be understood by one of ordinary skill viewing this disclosure that the exact structure, connections, and components can be varied to achieve the desired results. In addition, certain implementation may include hardware, software, and electronic components or modules that, for purposes of discussion, may be illustrated and described as if most of the components were implemented solely in hardware. However, one of ordinary skill in the art, and based on a reading of this disclosure would recognize that in certain configurations the electronic-based aspects may be implemented in software (e.g., stored on non-transitory computer-readable medium) executable by one or more processing units, such as any combination of one or more of a general-purpose processor, microprocessor, DSP, FPGA, application specific integrated circuits (“ASICs”), and/or other programmable logic device.. As such, it should be noted that a plurality of hardware and software-based devices, as well as a plurality of different structural components, may be utilized to implement the embodiments. For example, “servers,” “computing devices,” “controllers,” “processors,” etc., described in the specification can include one or more processing units, one or more computer-readable medium modules, one or more input/output interfaces, and various connections (e.g., a system bus) connecting the components.

1. A utility meter system comprising:
a meter housing;
at least one sensor connected to the meter housing and configured to be connected to a utility system, the at least one sensor configured for measuring at least one parameter of the utility system and generating at least one analog signal indicative of the at least one parameter;
at least one analog to digital converter connected to the at least one sensor, the at least one analog to digital converter configured to receive the at least one analog signal and convert the at least one analog signal to an at least one digital signal to obtain measured data;
a processing system including one or more processors;
a memory having a first region and a second region separate from the first region, wherein the first region includes compiled code having a first library that is used for communicating under a first protocol and the second region includes a second library that is used for communicating under a second protocol, and wherein access to the compiled code is limited by a virtual wrapper, which is configured to conceal implementation details of communication under the second protocol,
the memory storing instructions that, when executed by the one or more processors, cause the system to,
receive instructions to communicate using the first protocol; and
execute at least one first service provided by the second library, wherein the at least one first service is accessible via at least one function pointer implementing at least one virtual hook that is disposed in a vector call table in connection with the virtual wrapper.

2. The utility meter system of claim 1, wherein the instructions executed by the one or more processors, further cause the system to:
receive instructions to communicate using the second protocol; and
execute at least one second service provided by the second library, wherein the at least one second service is directly accessible from the second library.

3. The utility meter system of claim 1, wherein the first library is a duplicate of the second library, in which the first library includes a set of first global variable identical to a set of second global variable in the second library, and wherein at least one of the wrapper or the compiled code conceal the first global variables in the first library such that one or more modifications to at least one specific global variable in the second library is not reflected in a corresponding global variable in the first library.

4. The utility meter system of claim 1, wherein the first protocol corresponds to serial communication and the second protocol corresponds to communicating over an IP network.

5. The utility meter system of claim 1, wherein the first library provides functionality to allow communication using a UDP protocol and the second library provides functionality to allow communication using an MS/TP protocol.

6. The utility meter system of claim 1, wherein the wrapper comprises a mapping component configured to constrain memory access by exposing, via the first region, only predetermined memory structures usable for communication between the first protocol and the compiled code embedded in the wrapper.

7. The utility meter system of claim 1, wherein the wrapper comprises a pipe component configured to manage communications to and from the compiled code embedded in the wrapper via at least one request/reply conduit.

8. A utility meter system comprising:
a meter housing;
at least one sensor connected to the meter housing and configured to be connected to a utility system, the at least one sensor configured for measuring at least one parameter of the utility system and generating at least one analog signal indicative of the at least one parameter;
at least one analog to digital converter connected to the at least one sensor, the at least one analog to digital converter configured to receive the at least one analog signal and convert the at least one analog signal to at least one digital signal to obtain measured data;
a processing system including one or more processors, the processing system configured for receiving the at least one digital signal;
memory connected to the processing system; and
wherein the processing system is configured to implement a self-describing database stored in the memory, the self-describing database including a first tier of information storing objects associated with the utility meter and a second tier of information storing metadata associated with the objects, the metadata including at least a data dictionary associated with one or more of the objects.

9. The utility meter system of claim 8, wherein the objects stored in the first tier of information include at least one of meter readings, meter information, or rate structure.

10. The utility meter system of claim 8, wherein the data dictionary includes, for each object, information on the object's purpose, unit of measurement, valid ranges, and data types.

11. The utility meter system of claim 8, wherein the self-describing database is configured to support query-based retrieval of information, including structured query language queries, to extract specific data based on criteria including at least one of time periods, consumption rates, and locations.

12. The utility meter system of claim 8, wherein the self-describing database includes access information that defines users that can read and write specific data entries stored by the utility meter.

13. A system for updating a utility meter, the system comprising:
a utility meter including a processing system, memory, and a communication interface,
wherein the processing system is configured to,
receive a JavaScript Object Notation (JSON) file containing one or more configuration parameters via the communication interface,
parse the JSON file to extract the one or more configuration parameters,
validate the extracted configuration parameters to determine valid parameters and separate invalid parameters from the valid parameters,
apply the valid parameters to update a configuration of the utility meter, and
store the updated configuration in the memory.

14. The system of claim 13, wherein the JSON file is one of a plurality of JSON files, each JSON file configured to group related features and updates together, including a first JSON file configured to configure a communication protocol in the utility meter and a second JSON file configured to configure connection information of the utility meter.

15. The system of claim 13, wherein the processing system is further configured to allow devices with older firmware to receive updates by permitting the utility meter to ignore parameters in the JSON file that are unknown to the utility meter.

16. The system of claim 13, wherein the processing system is further configured to generate a JSON file containing current configuration parameters and settings of the utility meter for retrieval by a user, and wherein security-related parameters in the generated JSON file are automatically masked based on a user's access level.

17. A system for creating and distributing a firmware update file for a utility meter comprising:
a plurality of utility meters configured to receive and implement an update file;
one or more processors executing a firmware update process configured to:
create the update file in a hex format containing one or more configuration parameters for one or more utility meters;
convert the update file from the hex format to a binary format;
divide the update file into a plurality of sections, each section containing a checksum and a data length;
apply compression and encryption to the plurality of sections;
create a file header including information about a target device for the firmware, a version, a build date, and a manifest;
assemble the file header with the plurality of sections into a combined file;
compute a checksum value for the combined file; and
update the checksum value in the file header of the combined file; and
a communication interface configured to transmit the combined file to the plurality of utility meters.

18. The system of claim 17, wherein the checksum value computed for the combined file is a cyclic redundancy check value.

19. The system of claim 17, wherein the file header is configured to allow software and a respective utility meter to verify integrity and security of the combined file prior to applying the firmware update.

20. The system of claim 17, wherein the combined file is configured to receive a specific file extension identifying the combined file as intended for a specific device type including a utility meter.
